(19) United States
(12) Patent Application Publication
(10) Pub. No.: US 2022/0163582 A1
(43) Pub. Date: May 26, 2022

(54) FAULT POINT LOCATING APPARATUS, FAULT POINT LOCATING SYSTEM, FAULT POINT LOCATING METHOD, AND NON-TRANSITORY COMPUTER-READABLE MEDIUM

(71) Applicant: NEC Corporation, Minato-ku, Tokyo (JP)

(72) Inventor: Manabu KUSUMOTO, Tokyo (JP)

(73) Assignee: NEC Corporation, Minato-ku, Tokyo (JP)

(21) Appl. No.: 17/440,392

(22) PCT Filed: Mar. 26, 2019
(86) PCT No.: PCT/JP2019/012924

§ 371 Date: Sep. 17, 2021

(51) Int. Cl. G01R 31/08

(52) U.S. Cl. CPC G01R 31/086; G01R 31/088

(57) ABSTRACT

A fault point locating apparatus according to the present disclosure includes: a frequency characteristic calculation unit configured to calculate frequency characteristics after occurrence of a fault; and a post-fault-occurrence model analysis unit configured to add a model of a fault point to a pre-fault-occurrence model of a power transmission-and-distribution network so as to match the frequency characteristics after the occurrence of the fault and create a post-fault-occurrence model, thereby locating a fault point.

### TECHNICAL FIELD

The present disclosure relates to a fault point locating apparatus for locating a fault point in a power transmission-and-distribution network, a fault point locating system, a fault point locating method, and a program for locating a fault point.

### BACKGROUND ART

A trouble in which an abnormal current flows through a power transmission-and-distribution network may occur due to factors such as on-contact of the network with trees and wildlife, breakdown of the equipment, thunder, and the like. When a switch or the like operates in order to keep the power transmission-and-distribution network safe from such an abnormal current, a power outage is caused. Power outages have a huge impact on people's lives and economic activities, and thus it is necessary to restore power as quickly as possible. To that end, it is necessary to quickly locate the point where a fault has occurred and eliminate the cause of the fault, to thereby ensure safety of the power transmission-and-distribution network.

Accordingly, as a method of specifying a fault point, a method has been proposed in which a surge current generated when a fault occurs is measured using two measurement devices disposed across the fault point and the fault point is located based on the difference between the respective arrival times of the surge current at the two measurement devices (Patent Literature 1). Since the surge current propagates at a high speed in this method, it is necessary for the two measurement devices to synchronize time with high precision and to have high sampling rates. Therefore, it is necessary to provide equipment that synchronizes time with high precision, an A/D convertor having a high sampling rate, and the like.

Other than the method mentioned above, a method has been proposed in which a capacitor is installed between a power distribution line and the ground, and a ground fault point is sought for based on the inclination of the waveform of the current flowing through the capacitor (Patent Literature 2). In this method, the ground fault point is located based on the capacitance of the installed capacitor and the rise of the current generated due to the inductance of the wiring. Therefore, it is necessary to install a capacitor between a power distribution line and the ground and find an inductance of each wiring. Accordingly, with these methods, there has been a problem that enormous installation cost is incurred.

In order to solve the problem mentioned above, a method of locating a ground fault point based on a resonance frequency in a power distribution system after the occurrence of a fault has also been proposed (Patent Literature 3). In this method, a model of a power distribution system is created and a resonance frequency in the case where a ground fault occurs is calculated for each point in advance, and by comparing the calculated resonance frequency with the resonance frequency observed at each point where the ground fault has actually occurred, the fault point is located.

### CITATION LIST

### Patent Literature

Patent Literature 1: Japanese Unexamined Patent Application Publication No. S63-206668

Patent Literature 2: Japanese Unexamined Patent Application Publication No. 2008-157862

Patent Literature 3: Japanese Unexamined Patent Application Publication No. 2005-300205

### SUMMARY OF INVENTION

### Technical Problem

However, in the method of obtaining the resonance frequency in advance by performing simulation processing (Patent Literature 3), the resonance frequency changes due to a change in the characteristics of the power transmission-and-distribution network or a change in the surrounding environment such as a change in the weather. Therefore, there has been a problem such as degradation in the precision of locating a fault point.

An object of the present disclosure is to provide a fault point locating apparatus, a fault point locating system, a fault point locating method, and a program for locating a fault point, each of which is configured to adapt to changes in the characteristics of a power transmission-and-distribution network that change day by day, and to realize highly-precise locating of a fault point.

### Solution to Problem

A fault point locating apparatus according to an aspect of the present disclosure includes:

a frequency characteristic calculation unit configured to calculate frequency characteristics after occurrence of a fault; and

a post-fault-occurrence model analysis unit configured to add a model of a fault point to a pre-fault-occurrence model of a power transmission-and-distribution network so as to match the frequency characteristics after the occurrence of the fault and create a post-fault-occurrence model, thereby locating a fault point.

A fault point locating apparatus according to an aspect of the present disclosure includes:

a frequency characteristic calculation unit configured to calculate frequency characteristics before and after occurrence of a fault;

a pre-fault-occurrence model analysis unit configured to create a pre-fault-occurrence model of a power transmission-and-distribution network so as to match the frequency characteristics before the occurrence of the fault; and

a post-fault-occurrence model analysis unit configured to add a model of a fault point to the pre-fault-occurrence model so as to match the frequency characteristics after the occurrence of the fault and create a post-fault-occurrence model, thereby locating a fault point.

A fault point locating system according to an aspect of the present disclosure includes:

the above-mentioned fault point locating apparatus; and

a switch information acquisition unit connected to a switch provided in the power-transmission-and-distribution network and configured to acquire a waveform before the occurrence of the fault.

A fault point locating method according to an aspect of the present disclosure includes performing, by a computer, the steps of:

calculating frequency characteristics after occurrence of a fault; and

adding a model of a fault point to a pre-fault-occurrence model of a power transmission-and-distribution network so as to match the frequency characteristics after the occurrence of the fault and creating a post-fault-occurrence model, thereby locating a fault point.

A fault point locating method according to an aspect of the present disclosure includes performing, by a computer, the processes of:

calculating frequency characteristics before and after occurrence of a fault;

creating a pre-fault-occurrence model of a power transmission-and-distribution network so as to match the frequency characteristics before the occurrence of the fault; and

creating a post-fault-occurrence model by adding a model of a fault point to the pre-fault-occurrence model so as to match the frequency characteristics after the occurrence of the fault and creating a post-fault-occurrence model, thereby locating a fault point based on the post-fault-occurrence model.

A program for locating a fault point according to an aspect of the present disclosure causes a computer to execute:

frequency characteristics calculation processing of calculating frequency characteristics after occurrence of a fault; and

post-failure-occurrence model analytical processing of adding a model of a fault point to a pre-fault-occurrence model so as to match the frequency characteristics after the occurrence of the fault and creating a post-fault-occurrence model, thereby locating a fault point.

A program for locating a fault point according to an aspect of the present disclosure causes a computer to execute:

frequency characteristics calculation processing of calculating frequency characteristics before and after occurrence of a fault;

pre-fault-occurrence model analytical processing of creating a pre-failure-occurrence model of a power transmission-and-distribution network so as to match the frequency characteristics before the occurrence of the fault; and

post-fault-occurrence model analytical processing of adding a model of a fault point to the pre-fault-occurrence model so as to match the frequency characteristics after the occurrence of the fault and creating a post-fault-occurrence model, thereby locating a fault point based on the post-fault-occurrence model.

### Advantageous Effects of Invention

According to the present disclosure, a fault point locating apparatus, a fault point locating system, a fault point locating method, and a program for locating a fault point, each of which is configured to locate a fault point with high precision, can be provided.

### BRIEF DESCRIPTION OF DRAWINGS

FIG. 1 is a block diagram showing a configuration of a fault point locating apparatus according to a first example embodiment of the present disclosure;

FIG. 2 is a block diagram showing a configuration of a fault point locating apparatus according to a second example embodiment of the present disclosure;

FIG. 3 is a block diagram showing a configuration of a fault point locating apparatus according to a third example embodiment of the present disclosure;

FIG. 4 is a flowchart describing the operation of a frequency characteristic calculation unit according to the third example embodiment of the present disclosure;

FIG. 5 is a flowchart describing the operation of a pre-fault-occurrence model analysis unit according to the third example embodiment of the present disclosure;

FIG. 6 is a flowchart describing how parameter fitting is carried out according to the third example embodiment of the present disclosure;

FIG. 7 is a flowchart describing the operation of a post-fault-occurrence model analysis unit according to the third example embodiment of the present disclosure;

FIG. 8 is a block diagram showing a configuration of a fault point locating apparatus according to a fourth example embodiment of the present disclosure;

FIG. 9 is a block diagram showing a configuration of a fault point locating apparatus according to a fifth example embodiment of the present disclosure; and

FIG. 10 is a block diagram showing a configuration of a fault point locating apparatus according to a sixth example embodiment of the present disclosure.

### EXAMPLE EMBODIMENT

First, an outline of example embodiments of the present disclosure will be described.

The present disclosure relates to fault point locating in which when a fault occurs within a section of a power transmission-and-distribution network, the point where the fault has occurred s estimated. In calculating the frequency characteristics of the power transmission-and-distribution network, a model is created based on the line type and the length of the power transmission-and-distribution line, the connection information, and the like, the capacitance of the transformer, the system information such as the load information pertaining to connected devices and the like. This model is used in performing simulation processing of simulating the operation of an electric circuit, and reproduces the behavior of a current and a voltage at each point. Examples of the model include a model that indicates the electrical characteristics of each component (e.g. a transformer, a power supply, wiring, etc.) and a model that reproduces the characteristics of the line network (here, the power transmission-and-distribution network) by combining each aforementioned model. In other words, in the present specification, the pre-fault-occurrence model and the post-fault-occurrence model are configured by combining the models that indicate the electrical characteristics of the components. The fault point model is a model indicating the electrical behavior at the fault point. At this time, the parameters such as the ground capacitance and the inductance per unit length change not only due to the line type of the power transmission-and-distribution line but also due to the change in the surrounding environment. Therefore, these parameters change daily depending on the state of dryness of the ground due to the weather and the state of the tress, and thus it is difficult to obtain these parameters in advance. It is, therefore, difficult to estimate these parameters accurately whereby the accurate values of the parameters remain unknown. Accordingly, these unknown parameters are determined by carrying out fitting based on the frequency characteristics that are exhibited in the waveform before the occurrence of the fault whereby the precision of the model can be enhanced. Further, by carrying out fitting using the post-fault-occurrence model obtained by adding the fault point model after further enhancing the precision of the model, the fault point can be located with high precision.

Hereinbelow, specific example embodiments to which the present disclosure is applied will be described in detail with reference to the drawings. However, the present disclosure is not limited to the example embodiments described below. Further, for the sake of clarifying the explanation, the following description and the drawings are simplified where appropriate.

### First Example Embodiment

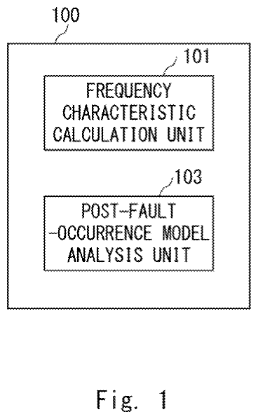

A first example embodiment of the present disclosure will be described with reference to FIG. 1.

A fault point locating apparatus 100 includes a frequency characteristic calculation unit 101 that calculates the frequency characteristics after the occurrence of a fault and a post-fault-occurrence model analysis unit 103 that adds a fault point model to a pre-fault-occurrence model so as to match the frequency characteristics after the occurrence of the fault and creates a post-fault-occurrence model, thereby locating the fault point.

As described above, according to the first example embodiment, a fault point can be located with high precision.

### Second Example Embodiment

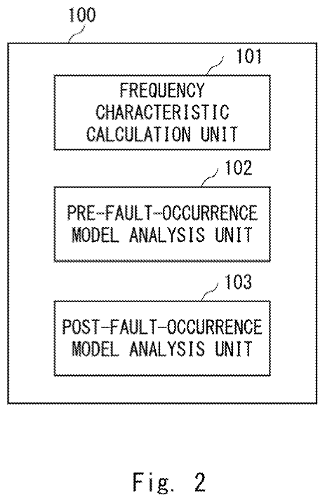

A second example embodiment of the present disclosure will be described with reference to FIG. 2.

A fault point locating apparatus 100 includes the frequency characteristic calculation unit 101 that calculates frequency characteristics before and after the occurrence of a fault, a pre-fault-occurrence model analysis unit 102 that creates a pre-fault-occurrence model of a power transmission-and-distribution network so as to match the frequency characteristics before the occurrence of the fault, and the post-fault-occurrence model analysis unit 103 that adds a fault point model to the pre-fault-occurrence model so as to match the frequency characteristics after the occurrence of the fault and creates a post-fault-occurrence model, thereby locating a fault point.

As described above, according to the second example embodiment, a fault point can be located with high precision.

### Third Example Embodiment

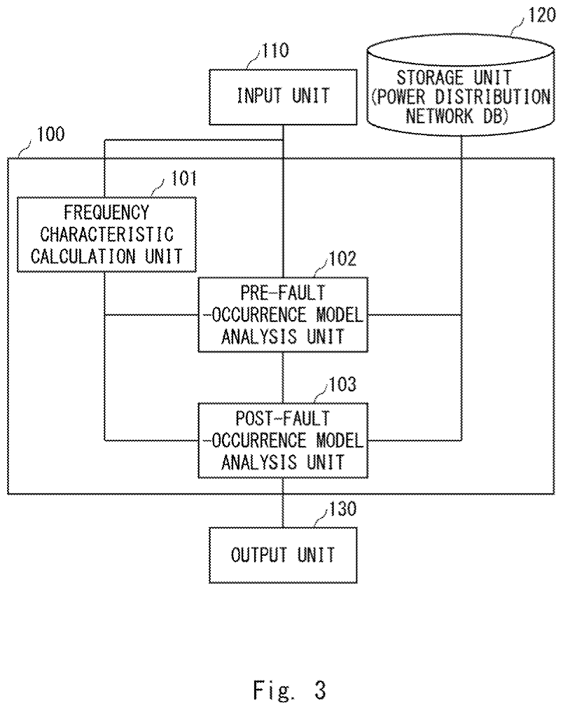

A configuration of a fault point locating system according to a third example embodiment of the present disclosure will be described with reference to FIG. 3. The fault point locating system includes a fault point locating apparatus 100, an input unit 110, a storage unit 120, and an output unit 130.

The fault point locating apparatus 100 is implemented by a computer and has a hardware configuration having a microcomputer at the center thereof, the microcomputer being configured of, for example, a CPU (Central Processing Unit) that performs calculation processing, a memory configured of a ROM (Read Only Memory) or a RAM (Random Access Memory) that stores operation programs and the like executed by the CPU, an interface (I/F) for inputting/outputting a signal from/to the outside, and the like. The CPU, the memory, and the interface unit are mutually connected with one another via a data bus.

The input unit 110 inputs a current waveform indicating a change in the current flowing through the power transmission-and-distribution network. Since this waveform is used only to obtain the frequency characteristics of the power transmission-and-distribution network, and there is no need to provide an A/D (Analog/Digital) convertor having a high sampling rate as that used in the surge method. The output unit 130 displays the fault point located by the fault point locating apparatus, and examples thereof include a liquid crystal display, a printer, and the like.

The fault point locating apparatus 100 includes a functional calculation unit for performing each of the pieces of processing. The fault point locating apparatus 100 includes the frequency characteristic calculation unit 101, the pre-fault-occurrence model analysis unit 102, and a post-fault-occurrence model analysis unit 103.

The frequency characteristic calculation unit 101 calculates the actual frequency characteristics before and after the occurrence of the fault based on the current waveform before and after the occurrence of the fault input from the power transmission-and-distribution network.

The pre-fault-occurrence model analysis unit 102 constructs a simulation model for a pre-fault-occurrence model by combining the model of each part of the power transmission-and-distribution system (e.g. models of a power supply, a transformer, wiring and the like) based on the type and the length of the wiring, the connection information, and information on the transformer of the power transmission-and-distribution system in which a fault has occurred. At this time, the parts of the parameters that change in the model of each part are set as the unknown parameters. Then, the unknown parameters are changed so that the frequency characteristics obtained from the simulation processing performed using the aforementioned model approach the actual frequency characteristics before the occurrence of the fault obtained by the frequency characteristic calculation unit 101. By repeating this process, the frequency characteristics of the simulation model are made to fit the actual frequency characteristics calculated by the frequency characteristic calculation unit 101 (referred to as the parameter fitting).

The post-fault-occurrence model analysis unit 103 creates a pre-fault-occurrence model by adding a fault point model (a component model) in which the fault point (also referred to as the fault location) and the parameters of the characteristics of the fault (e.g. the parameters for reproducing the behavior of the fault point such as the resistance to the ground in the case of a model of a ground fault) are the unknown parameters to the pre-fault-occurrence model in which the unknown parameters are fitted created by the pre-fault-occurrence model analysis unit 102. The frequency characteristic calculation unit 101 repeats the simulation processing so that the frequency characteristics match the actual frequency characteristics after the occurrence of the fault obtained by the frequency characteristic calculation unit 101 by changing the unknown parameters of the post-fault-occurrence model. By this configuration, it is possible to precisely obtain the parameters of the fault point model that change before and after the occurrence of the fault by carrying out fitting using the actual frequency characteristics data before the occurrence of the fault after further enhancing the precision of the model, and enhancing the precision of the model. As a result, the fault point can be located with high precision.

### Operation

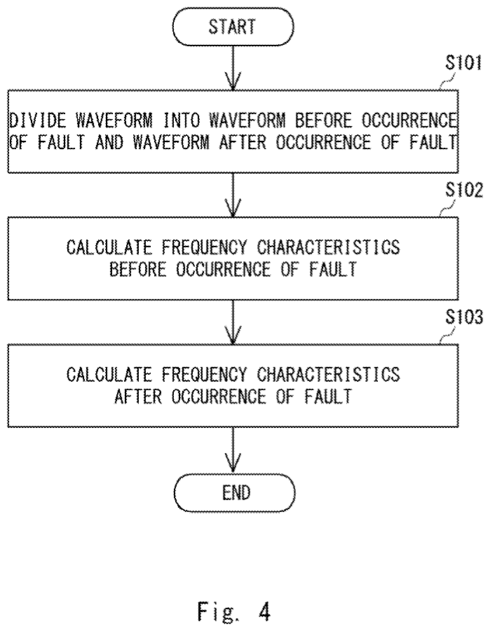

Next, the operation of the frequency characteristic calculation unit 101 according the third example embodiment will be described with reference to the flowchart shown in FIG. 4. First, the input waveform is divided into a waveform before the occurrence of a fault and a waveform after the occurrence of the fault (Step S101). Next, the frequency characteristics of the waveform before the occurrence of the fault is calculated (Step S102). These frequency characteristics can be calculated by, for instance, applying Fourier transform to the waveform. Other than that, there is a method of performing frequency analysis employing the maximum entropy method. Then, the frequency characteristics of the waveform after the occurrence of the fault are also calculated (Step S103). In the same way, the frequency characteristics of the waveform after the occurrence of the fault can be calculated by using Fourier transform or the maximum entropy method.

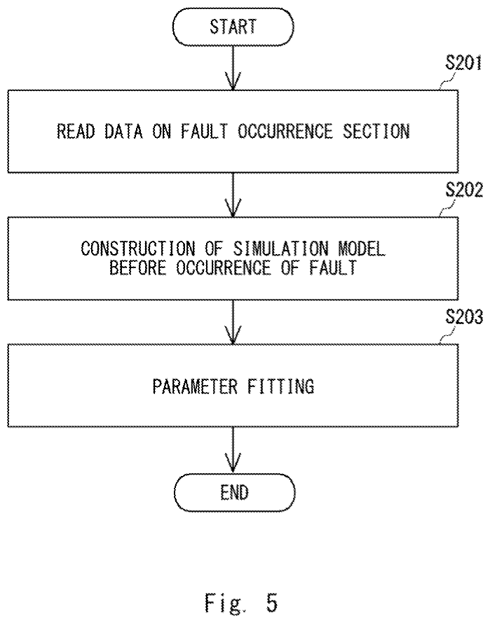

Next, the operation of the pre-fault-occurrence model analysis unit 102 unit according to the third example embodiment will be described with reference to a flowchart shown in FIG. 5. First, data related to information of the power transmission-and-distribution system in which a fault has occurred is read from the power distribution network database 120 (Step S201). At this time, the information on the power transmission-and-distribution system such as the line type and the length of each wiring, the information on the transformer, the load information pertaining to the connected devices, and the connection information of each part is acquired. Next, by combining the model of each part, a simulation model for the pre-fault-occurrence model is constructed (Step S202). Based on the information acquired in Step S201, the simulation model that comply with each part of the power transmission-and-distribution system (a model of each part) is fitted and the simulation model of each part is connected in accordance with the connection information of each part. As this time, unknown parameters are set for the characteristic parts that may change in the simulation model of each component. Next, parameter fitting is carried out for the unknown parameters so that they match the actual frequency characteristics before the occurrence of the fault (Step S203).

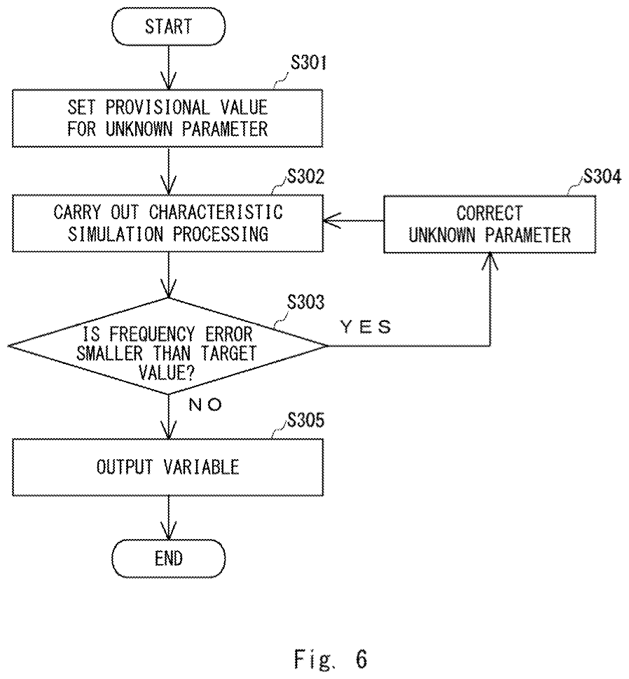

Next, the parameter fitting according to the third example embodiment (Step S203) will be described with reference to the flowchart shown in FIG. 6. First, a provisional value is set for each unknown parameter (Step S301). The provisional value may be, for instance, a value included in the model as a standard value. Alternatively, the provisional value may be a value obtained in the previously-performed simulation processing. Next, the frequency characteristic simulation processing is carried out in order to obtain the frequency characteristics (Step S302). The simulation processing can be performed by, for instance, using the EMTP (Electromagnetic Transients Program), SPICE (Simulation Program with Integrated Circuit Emphasis), or the like. As an example of the simulation processing, there is method of performing time analysis using the consumption current of each load as a source of noise and obtaining the frequency characteristics by using the Fourier transform. Alternatively, the frequency characteristics may be obtained from an impulse response or a step response. Further, as a signal source of the load, the frequency characteristics may be obtained by performing small-signal analysis.

Next, the frequency characteristic calculation unit 101 obtains a frequency characteristic error by comparing the actual frequency characteristics before the occurrence of the fault obtained by the frequency characteristic calculation unit 101 and the frequency characteristics obtained in the frequency characteristic simulation processing (Step S302). This frequency characteristic error may be obtained by taking the difference between the amplitude values at each frequency and adding up the differences. Alternatively, the amplitude value may be calculated as logarithm before taking the difference between the amplitude values at each frequency. Further, the peak of each frequency may be determined and the difference in the peaks of each frequency may be calculated as the error. When this error is smaller than the set target value, (NO in Step S303), a variable is output (Step S305). On the other hand, when the error is larger than the target value (YES in Step S303), the unknown parameters are corrected (Step 5304) and the frequency characteristic simulation processing is performed (Step S302). In Step 5304, the variable of the parameters is corrected using the optimization problem algorithm. As the optimization problem algorithm, for instance, Nelder-Mead method, a genetic algorithm, or particle swarm optimization can be employed.

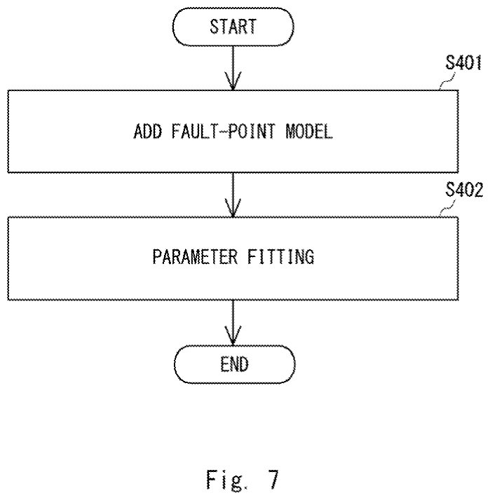

Next, the operation of the post-fault-occurrence model analysis unit 103 according to the third example embodiment will be described with reference to a flowchart shown in FIG. 7. First, a fault-point model is added to the model fitted by the pre-fault-occurrence model analysis unit 102 (Step S401). The fault-point model can be, for instance, a model of resistance or airgap, and the resistance, the airgap, and the connection point of the power transmission-and-distribution network, and the resistance value can be set as the unknown parameters. Further, as a disconnection model, a model of disconnecting a part of the power transmission-and-distribution network or a model of applying a voltage such as a model of thunder can be used. Fitting may be performed for the unknown parameters including selection of a model. Next, the parameter fitting is carried out (Step S402). In Step S402, the parameters are obtained using the optimization processing same as that performed in Step S203. Parameter fitting is carried out for the unknown parameters so that they match the actual frequency characteristics after the occurrence of the fault.

### Effect

The unknown parameters of the created model are determined by performing fitting based on the frequency characteristics that are exhibited in the waveform before the occurrence of the fault whereby the precision of the model can be enhanced. Further, by carrying out fitting using the post-fault-occurrence model obtained by adding the fault point model after further enhancing the precision of the model, the fault point can be located with high precision.

### Fourth Example Embodiment

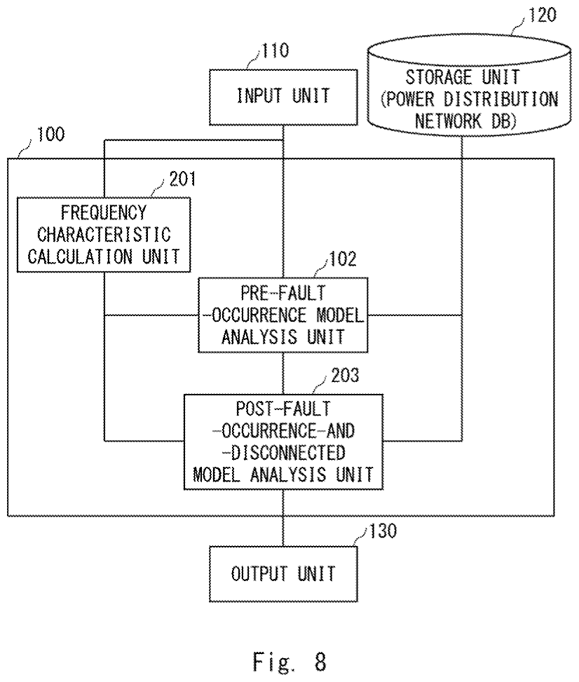

Next, a fourth example embodiment of the present disclosure will be described with reference to FIG. 8. In FIG. 8, the structural elements identical to those of the third example embodiment are denoted the reference symbols same as those of FIG. 3 and the redundant explanations thereof are omitted where appropriate. In the fourth example embodiment, the frequency characteristic calculation unit 101 and the post-fault-occurrence model analysis unit 103 are replaced by a frequency characteristic calculation unit 201 and a post-fault-occurrence-and-disconnected model analysis unit 203, respectively, from the third example embodiment, and these replaced parts will be described in detail below.

The frequency characteristic calculation unit 201 according to the fourth example embodiment calculated the frequency characteristics before and after the occurrence of a fault like similarly to the frequency characteristic calculation unit 101 according to the third example embodiment. Further, the frequency characteristic calculation unit 201 according to the fourth example embodiment calculates the frequency characteristics of the current waveform after the fault point has been isolated by a switch (not shown) provided in the power transmission-and-distribution network. Further, the post-fault-occurrence-and-disconnected model analysis unit 203 creates a model after the disconnection by the switch in addition to the post-fault-occurrence model created by the post-fault-occurrence model analysis unit 103, and adds the fault point to the created model. By this configuration, the model before the disconnection by the switch after the occurrence of the fault and the model after the disconnection by the switch after the occurrence of the fault are created. Fitting of the parameter that exhibits the fault point and the characteristics thereof after the occurrence of the fault is performed such that the frequency characteristics of the model before the disconnection by the switch after the occurrence of the fault matches the frequency characteristics before the disconnection by the switch after the occurrence of the fault calculated by the frequency characteristic calculation unit 201 match each other, and further, the frequency characteristics of the model after the disconnection by the switch after the occurrence of the fault matches the frequency characteristics after the power cutoff by the switch after the occurrence of the fault calculated by the frequency characteristic calculation unit 201.

### Effect

In the fourth example embodiment, fitting including the model after the disconnection by the switch provided in the power transmission-and-distribution network is carried out. The power transmission-and-distribution network after the disconnection by the switch is limited to the part from the fault point to the switch, and there are less elements that affect the frequency characteristics. Therefore, it is possible to locate the fault point with higher precision.

### Fifth Example Embodiment

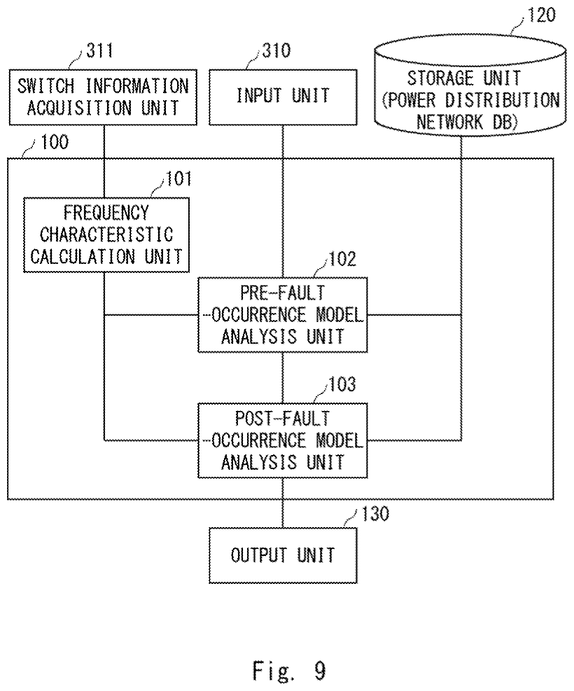

Next, a fifth example embodiment of the present disclosure will be described with reference to FIG. 9. In FIG. 9, the structural elements identical to those of the third example embodiment are denoted the reference symbols same as those of FIG. 3 and the redundant explanations thereof are omitted where appropriate. Referring to FIG. 9, comparing an input unit 310 according to the fifth example embodiment with the input unit 110 according to the third example embodiment and the input unit 110 according to the fourth example embodiment, the input unit 310 is connected only to the post-fault occurrence model analysis unit 102. Further, in the fifth example embodiment, a switch information acquisition unit 311 connected to the frequency characteristic calculation unit 101 is added.

The switch information acquisition unit 311 is connected to the switch provided in the power transmission-and-distribution network and observes the current waveform on a regular basis, and acquires and stores the current waveform when the switch (not shown) detects the overcurrent or the ground fault current. The switch information acquisition unit 311 passes the data of this current waveform to the frequency characteristic calculation unit 101 in accordance with a request from the fault point locating apparatus 100 whereby the fault point locating operation according to the fifth example embodiment can be realized. Further, the switch information acquisition unit 311 can function as the frequency characteristic calculation unit 101 and the pre-fault-occurrence model analysis unit 102. That is, the switch information acquisition unit 311 can calculate the frequency characteristics before the occurrence of the fault and create a pre-fault-occurrence model of the power transmission-and-distribution network so as to match the frequency characteristics before the occurrence of the fault.

### Effect

In the fifth example embodiment, the switch information acquisition unit 311 acquires the current waveform before the occurrence of the fault on a regular basis whereby it is possible to reliably acquire the characteristics before the occurrence of a fault. Further, by creating and analyzing the pre-fault-occurrence model before the occurrence of the fault, it is possible to create and analyze the post-fault-occurrence model immediately after the occurrence of the fault whereby it is possible to output the result of the fault point location within a short period of time.

### Sixth Example Embodiment

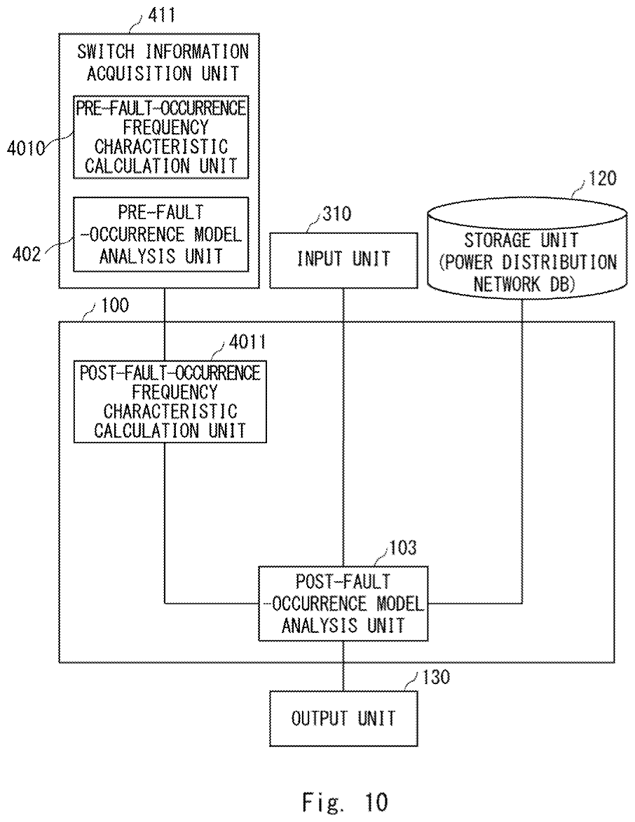

Next, a sixth example embodiment of the present disclosure will be described with reference to FIG. 10. In FIG. 10, the structural elements identical to those of the fifth example embodiment are denoted the reference symbols same as those of FIG. 9 and the redundant explanations thereof are omitted where appropriate. Referring to FIG. 10, comparing a switch information acquisition unit 411 according to the sixth example embodiment with the switch information acquisition unit 311 according to the fifth example embodiment, the switch information acquisition unit 411 includes a pre-fault-occurrence frequency characteristic calculation unit 4010 and a pre-fault-occurrence model analysis unit 402. Further, in the sixth example embodiment, a post-fault-occurrence frequency characteristic calculation unit 4011 is added in place of the frequency characteristic calculation unit 101. The switch information acquisition unit 411 is implemented by a computer and has a hardware configuration having a microcomputer at the center thereof, the microcomputer being configured of, for example, a CPU (Central Processing Unit) that performs calculation processing, a memory configured of a ROM (Read Only Memory) or a RAM (Random Access Memory) that stores operation programs and the like executed by the CPU, an interface (I/F) for inputting/outputting a signal from/to the outside, and the like. The CPU, the memory, and the interface unit are mutually connected with one another via a data bus.

The switch information acquisition unit 411 is connected to the switch (not shown) provided in the power transmission-and-distribution network and observes the current waveform on a regular basis, and acquires and stores the current waveform when the switch (not shown) detects the overcurrent or the ground fault current. The switch information acquisition unit 411 can calculate the frequency characteristics before the occurrence of the fault and create a pre-fault-occurrence model of the power transmission-and-distribution network so as to match the frequency characteristics before the occurrence of the fault.

### Effect

In the sixth example embodiment, the switch information acquisition unit 311 acquires the current waveform before the occurrence of the fault on a regular basis whereby it is possible to reliably acquire the characteristics before the occurrence of a fault. Further, by creating and analyzing the pre-fault-occurrence model before the occurrence of the fault, it is possible to create and analyze the post-fault-occurrence model immediately after the occurrence of the fault whereby it is possible to output the result of the fault point location within a short period of time.

### Examples

Next, operations in the example embodiments for carrying out the present disclosure will be described with reference to FIG. 9 and specific examples. The switch information acquisition unit 111 is connected to a switch (not shown) that detects the overcurrent or the ground fault current and disconnects the power transmission-and-distribution network. Since the switch monitors the current flowing through the power transmission-and-distribution line, the data of this current is acquired by the switch information acquisition unit 111. Further, it is not necessary that there be only one switch information acquisition unit 111, and a plurality of switch information acquisition units 111 can be connected to a plurality of disconnectors of the power transmission-and-distribution network, respectively. Further, the switch information acquisition unit 111 is connected to the fault point locating apparatus 100 via a communication line.

The switch information acquisition unit 111 disposed in the power transmission-and-distribution system acquires the current waveform at each point on a regular basis and transmits the current waveform to the fault point locating apparatus 100. The fault point locating apparatus 100 receives the waveform at each point and calculates the frequency characteristics in the frequency characteristic calculation unit 101. The calculation of the frequency characteristics is carried out by using the Fourier transform. At this time, the frequency of the AC power supply (50 Hz or 60 Hz) and its harmonic signal are filtered out.

Next, a pre-fault-occurrence model is constructed so as to match the frequency characteristics before the occurrence of the fault calculated by the pre-fault-occurrence model analysis unit 102 and parameter fitting is carried out for the unknown parameters. Specifically, first, a model of each part of the power transmission-and-distribution network is read from the power distribution network database 120. A model of each part of the power transmission-and-distribution network defined by the line type and the length of the power distribution network and configured of a distributed constant circuit is created. The model of each part is spliced together in accordance with the connection information of the power transmission-and-distribution network. Further, a standard value according to the line type is set for each of the resistance, the inductance, the capacitance, and the conductance per unit length of the wiring model, and values that can be changed are set as the unknown parameters. Further, a model of the power consumers at each point (a model in accordance with the power consumption amount) is connected as a load and is set as a signal source that generates a pink noise in accordance with the current consumption amount.

Next, the unknown parameters are used as the optimization parameters, and the optimized algorithm is used to obtain the unknown parameters. Based on an optimization program, the variables to be optimized are set as the unknown parameters, and simulation is carried out on a function based on the variables. The amplitude of the frequency characteristics at each point calculated by the frequency characteristic calculation unit 101 and the amplitude of the frequency characteristics obtained at each point by the simulation are compared with each other, and the result of summing the errors is output. The algorithm is run so as to minimize these errors. The simulation is obtained by carrying out a transient analysis using EMTP or SPICE and by performing the Fourier transform to the obtained result. Then, the parameters are stored.

Next, the overcurrent or the ground fault current is detected by the switch, and when a fault occurs, the switch information acquisition unit 111 acquires the current waveform transmitted from the power transmission-and-distribution system and transmits the acquired current waveform to the fault point locating apparatus 100. The waveform is calculated by the frequency characteristic calculation unit 101 and is transmitted to the post-fault-occurrence model analysis unit 103.

Next, the post-fault-occurrence model analysis unit 103 performs optimization of the model by adding the model of the fault point using the parameters for which fitting has been carried out to the model used in the post-fault-occurrence model analysis unit 102. The fault point model is a model of the resistance that changes the node of the power transmission-and-distribution network connected in accordance with the positional parameter. Then, the model is passed on to the optimization program, and optimization is carried out. Finally, the actual location of the fault is calculated from the positional parameter and passed on to the output unit 130. Lastly, the fault point is displayed on a map on a screen by the output unit 130.

In the aforementioned example, the program can be stored and provided to a computer using any type of non-transitory computer readable media. Non-transitory computer readable media include any type of tangible storage media. Examples of non-transitory computer readable media include magnetic storage media (such as floppy disks, magnetic tapes, hard disk drives, etc.), optical magnetic storage media (e.g. magneto-optical disks), CD-ROM (Read Only Memory), CD-R, CD-R/W, DVD (Digital Versatile Disc), BD (Blu-ray (registered trademark) disc), and semiconductor memories (such as mask ROM, PROM (Programmable ROM), EPROM (Erasable PROM), flash ROM, RAM (Random Access Memory), etc.). The program may be provided to a computer using any type of transitory computer readable media. Examples of transitory computer readable media include electric signals, optical signals, and electromagnetic waves. Transitory computer readable media can provide the program to a computer via a wired communication line such as electric wires and optical fibers or a wireless communication line.

Note that the present disclosure is not limited to the above-described example embodiments, and can be naturally changed variously without departing from the gist of the present disclosure. The plurality of examples described above can be implemented by combining the examples as appropriate.

Further, the steps of the processing performed in the fault point locating apparatus described in the aforementioned various example embodiments can also be the steps for carrying out the fault point locating method. The fault point locating method includes the following steps. The fault point locating method includes the steps of: calculating the frequency characteristics after the occurrence of a fault; and adding a model of a fault point to a pre-fault-occurrence model of a power transmission-and-distribution network so as to match the frequency characteristics after the occurrence of the fault and creating a post-fault-occurrence model, thereby locating the fault point. Alternatively, the fault point locating method includes the step of: calculating the frequency characteristics before and after the occurrence of a fault; creating a pre-fault-occurrence model of a power transmission-and-distribution network so as to match the frequency characteristics after the occurrence of the fault; and adding a model of a fault point to the pre-fault-occurrence model of a power transmission-and-distribution network so as to match the frequency characteristics after the occurrence of the fault and creating a post-fault-occurrence model, thereby locating the fault point based on the post-fault-occurrence model. Note that other examples are as described in the aforementioned various example embodiments. Further, the fault point locating program is a program for causing a computer to execute the fault point locating method described above.

The whole or part of the example embodiments disclosed above can be described as, but not limited to, the following supplementary notes.

### Supplementary Note 1

A fault point locating apparatus comprising:

a frequency characteristic calculation unit configured to calculate frequency characteristics after occurrence of a fault; and

a post-fault-occurrence model analysis unit configured to add a model of a fault point to a pre-fault-occurrence model of a power transmission-and-distribution network so as to match the frequency characteristics after the occurrence of the fault and create a post-fault-occurrence model, thereby locating a fault point.

### Supplementary Note 2

The fault point locating apparatus described in Supplementary note 1, wherein the post-fault-occurrence model analysis unit is configured to carry out fitting after the occurrence of the fault for both a model before disconnection of a fault point and a model after disconnection of the fault point so as to match the frequency characteristics after the occurrence of the fault, the disconnection of the fault point being performed by a switch provided in the power transmission-and-distribution network.

### Supplementary Note 3

A fault point locating apparatus comprising:

a frequency characteristic calculation unit configured to calculate frequency characteristics before and after occurrence of a fault;

a pre-fault-occurrence model analysis unit configured to create a pre-fault-occurrence model of a power transmission-and-distribution network so as to match the frequency characteristics before the occurrence of the fault; and

a post-fault-occurrence model analysis unit configured to add a model of a fault point to the pre-fault-occurrence model so as to match the frequency characteristics after the occurrence of the fault and create a post-fault-occurrence model, thereby locating a fault point.

### Supplementary Note 4

The fault point locating apparatus described in Supplementary note 3, wherein the pre-fault-occurrence model analysis unit is configured to carry out fitting of the pre-fault-occurrence model in which characteristics of a wiring of the power transmission-and-distribution network are set as unknown parameters so as to match the frequency characteristics before the occurrence of the fault.

### Supplementary Note 5

The fault point locating apparatus described in any one of Supplementary notes 1 to 4, wherein the frequency characteristic calculation unit is configured to calculate the frequency characteristics by carrying out the Fourier conversion of a waveform after eliminating harmonics.

### Supplementary Note 6

A fault point locating system comprising:

the fault point locating apparatus described in any one of Supplementary notes 1 to 5; and

a switch information acquisition unit connected to a switch provided in the power-transmission-and-distribution network and configured to acquire a waveform before the occurrence of the fault.

### Supplementary Note 7

The fault point locating system described in Supplementary note 6, wherein the switch information acquisition unit is configured to calculate frequency characteristics before the occurrence of the fault and create a pre-fault-occurrence model of the transmission network so as to match the frequency characteristics before the occurrence of the fault.

### Supplementary Note 8

A fault point locating method comprising performing, by a computer, the steps of:

calculating frequency characteristics after occurrence of a fault; and

adding a model of a fault point to a pre-fault-occurrence model of a power transmission-and-distribution network so as to match the frequency characteristics after the occurrence of the fault and creating a post-fault-occurrence model, thereby locating a fault point.

### Supplementary Note 9

The fault point locating method described in Supplementary note 8, wherein fitting is carried out after the occurrence of the fault for both a model before disconnection of a fault point and a model after disconnection of the fault point so as to match the frequency characteristics after the occurrence of the fault, the disconnection of the fault point being performed by a switch provided in the power transmission-and-distribution network.

### Supplementary Note 10

A fault point locating method comprising performing, by a computer, the processes of:

calculating frequency characteristics before and after occurrence of a fault;

creating a pre-fault-occurrence model of a power transmission-and-distribution network so as to match the frequency characteristics before the occurrence of the fault; and

creating a post-fault-occurrence model by adding a model of a fault point to the pre-fault-occurrence model so as to match the frequency characteristics after the occurrence of the fault and creating a post-fault-occurrence model, thereby locating a fault point based on the post-fault-occurrence model.

### Supplementary Note 11

The fault point locating method according to Supplementary note 10, wherein fitting of the pre-fault-occurrence model in which the characteristics of the wiring of the power transmission-and-distribution network are set as unknown parameters is carried out so as to match the frequency characteristics before the occurrence of the fault.

### Supplementary Note 12

A program for causing a computer to execute:

frequency characteristics calculation processing of calculating frequency characteristics after occurrence of a fault; and

post-failure-occurrence model analytical processing of adding a model of a fault point to a pre-fault-occurrence model so as to match the frequency characteristics after the occurrence of the fault and creating a post-fault-occurrence model, thereby locating a fault point.

### Supplementary Note 13

A program for causing a computer to execute:

frequency characteristics calculation processing of calculating frequency characteristics before and after occurrence of a fault;

pre-fault-occurrence model analytical processing of creating a pre-failure-occurrence model of a power transmission-and-distribution network so as to match the frequency characteristics before the occurrence of the fault; and

post-fault-occurrence model analytical processing of adding a model of a fault point to the pre-fault-occurrence model so as to match the frequency characteristics after the occurrence of the fault and creating a post-fault-occurrence model, thereby locating a fault point based on the post-fault-occurrence model.

### INDUSTRIAL APPLICABILITY

The present disclosure is applicable for carrying out fault point locating of a power transmission-and-distribution network.

### REFERENCE SIGNS LIST

100 FAULT POINT LOCATING APPARATUS
101 FREQUENCY CHARACTERISTIC CALCULATION UNIT
102 PRE-FAULT-OCCURRENCE MODEL ANALYSIS UNIT
103 POST-FAULT-OCCURRENCE MODEL ANALYSIS UNIT
110 INPUT UNIT
120 STORAGE UNIT
130 INPUT UNIT
201 FREQUENCY CHARACTERISTIC CALCULATION UNIT
203 POST-FAULT-OCCURRENCE-AND-DISCONNECTED MODEL ANALYSIS UNIT
310 INPUT UNIT
311 SWITCH INFORMATION ACQUISITION UNIT
4010 PRE-FAULT-OCCURRENCE FREQUENCY CHARACTERISTIC CALCULATION UNIT
4011 POST-FAULT-OCCURRENCE FREQUENCY CHARACTERISTIC CALCULATION UNIT
402 PRE-FAULT-OCCURRENCE MODEL ANALYSIS UNIT
411 SWITCH INFORMATION ACQUISITION UNIT

What is claimed is:

1. A fault point locating apparatus comprising:
a frequency characteristic calculation unit configured to calculate frequency characteristics after occurrence of a fault; and
a post-fault-occurrence model analysis unit configured to add a model of a fault point to a pre-fault-occurrence model of a power transmission-and-distribution network so as to match the frequency characteristics after the occurrence of the fault and create a post-fault-occurrence model, thereby locating a fault point.

2. The fault point locating apparatus according to claim 1, wherein the post-fault-occurrence model analysis unit is configured to carry out fitting after the occurrence of the fault for both a model before disconnection of a fault point and a model after disconnection of the fault point so as to match the frequency characteristics after the occurrence of the fault, the disconnection of the fault point being performed by a switch provided in the power transmission-and-distribution network.

3-4. (canceled)

5. The fault point locating apparatus according to claim 1, wherein the frequency characteristic calculation unit is configured to calculate the frequency characteristics by carrying out the Fourier conversion of a waveform after eliminating harmonics.

6. A fault point locating system comprising:
the fault point locating apparatus according to claim 1; and
a switch information acquisition unit connected to a switch provided in the power-transmission-and-distribution network and configured to acquire a waveform before the occurrence of the fault.

7. The fault point locating system according to claim 6, wherein the switch information acquisition unit is configured to calculate frequency characteristics before the occurrence of the fault and create a pre-fault-occurrence model of the transmission network so as to match the frequency characteristics before the occurrence of the fault.

8. A fault point locating method comprising:
calculating frequency characteristics after occurrence of a fault; and
adding a model of a fault point to a pre-fault-occurrence model of a power transmission-and-distribution network so as to match the frequency characteristics after the occurrence of the fault and creating a post-fault-occurrence model, thereby locating a fault point.

9. The fault point locating method according to claim 8, wherein fitting is carried out after the occurrence of the fault for both a model before disconnection of a fault point and a model after disconnection of the fault point so as to match the frequency characteristics after the occurrence of the fault, the disconnection of the fault point being performed by a switch provided in the power transmission-and-distribution network.

10-11. (canceled)

12. A non-transitory computer readable medium storing a program for causing a computer to execute:
frequency characteristics calculation processing of calculating frequency characteristics after occurrence of a fault; and
post-failure-occurrence model analytical processing of adding a model of a fault point to a pre-fault-occurrence model so as to match the frequency characteristics after the occurrence of the fault and creating a post-fault-occurrence model, thereby locating a fault point.

13. (canceled)
